(19) United States
(12) Patent Application Publication
(10) Pub. No.: US 2013/0256719 A1
(43) Pub. Date: Oct. 3, 2013

(54) LIGHT EMITTING DEVICE

(71) Applicants: Masatomi Harada, Osaka-shi (JP); Nobutoshi Arai, Osaka-shi (JP)

(72) Inventors: Masatomi Harada, Osaka-shi (JP); Nobutoshi Arai, Osaka-shi (JP)

(73) Assignee: Sharp Kabushiki Kaisha, Osaka (JP)

(21) Appl. No.: 13/878,325

(22) PCT Filed: Jul. 22, 2011
(86) PCT No.: PCT/JP2011/066720

§ 371 Date: Jun. 12, 2013

(30) Foreign Application Priority Data
Oct. 8, 2010 (JP) 2010-228751

(51) Int. Cl. H01L 33/14

(52) U.S. Cl. CPC H01L 33/145
USPC 257/94

(57) ABSTRACT

A light emitting device according to the present invention comprises: a light emitting element including a semiconductor layer, a first electrode, a dielectric layer sandwiched between the semiconductor layer and the first electrode, and a light emitter; and a power supply circuit for applying a voltage between the semiconductor layer and the first electrode, wherein the light emitter is formed in at least one region of regions in the semiconductor layer, in the dielectric layer, between the semiconductor layer and the dielectric layer, and between the first electrode and the dielectric layer, the light emitting element emits light in one of first and second cases, but does not substantially emit light in the other case, the first case using a current applied to the dielectric layer under a condition that the semiconductor layer serves as a positive electrode and the first electrode serves as a negative electrode, the second case using a current applied to the dielectric layer under a condition that the semiconductor layer serves as the negative electrode and the first electrode serves as the positive electrode, and the power supply circuit is electrically connected to each of the semiconductor layer and the first electrode so that a unidirectional current flows in the dielectric layer while the light emitting element emits the light.

### TECHNICAL FIELD

The present invention relates to a light emitting device.

### BACKGROUND ART

Inorganic electroluminescent (EL) elements have attracted attention because of its long lifetime and power-saving function. In order to make the inorganic EL element emit light, it is necessary to apply a voltage of 200 to 300 V to the inorganic EL element. A conventional power supply device for applying the voltage to the inorganic EL element has a basic configuration in which a commercial AC voltage is boosted and applied to the inorganic EL element, and the AC voltage having a constant voltage and a constant frequency is outputted to make the inorganic EL element emit light (refer to a patent document 1). More specifically, there is a method for applying a sine-wave voltage to the inorganic EL element through a voltage-boost circuit of a series resonance circuit of an electric current resonance type.

### PRIOR ART DOCUMENTS

### Patent Documents

Patent Document 1: Japanese Patent Laid-open Publication No. 2006-269137

### SUMMARY OF THE INVENTION

### Problems to be Solved by the Invention

However, when the voltage is applied from the conventional power supply device to the inorganic EL element to make the inorganic EL element emit light, there is a problem that the inorganic EL element generates heat.

The present invention was made in such circumstance, and it provides a light emitting device in which heat generation can be suppressed while a voltage is applied.

### Solution to the Problems

The present invention provides a light emitting device comprising: a light emitting element including a semiconductor layer, a first electrode, a dielectric layer sandwiched between the semiconductor layer and the first electrode, and a light emitter; and a power supply circuit for applying a voltage between the semiconductor layer and the first electrode, wherein the light emitter is formed in at least one region of regions in the semiconductor layer, in the dielectric layer, between the semiconductor layer and the dielectric layer, and between the first electrode and the dielectric layer, the light emitting element emits light in one of first and second cases, but does not substantially emit light in the other case, the first case using a current applied to the dielectric layer under a condition that the semiconductor layer serves as a positive electrode and the first electrode serves as a negative electrode, the second case using a current applied to the dielectric layer under a condition that the semiconductor layer serves as the negative electrode and the first electrode serves as the positive electrode, and the power supply circuit is electrically connected to each of the semiconductor layer and the first electrode so that a unidirectional current flows in the dielectric layer while the light emitting element emits the light.

### Effect of the Invention

According to the present invention, the light emitting element includes the semiconductor layer, the first electrode, the dielectric layer sandwiched between the semiconductor layer and the first electrode, and the light emitter, and the light emitter is formed in at least one region of regions in the semiconductor layer, in the dielectric layer, between the semiconductor layer and the dielectric layer, and between the first electrode and the dielectric layer, so that when the voltage is applied between the semiconductor layer and the first electrode, the light emitting element can emit the light.

According to the present invention, the light emitting element emits light in one of first and second cases, but does not substantially emit light in the other case, the first case using a current applied to the dielectric layer under a condition that the semiconductor layer serves as a positive electrode and the first electrode serves as a negative electrode, the second case using a current applied to the dielectric layer under a condition that the semiconductor layer serves as the negative electrode and the first electrode serves as the positive electrode. Therefore, when the voltage is applied to the light emitting element such that the current flows in the dielectric layer in the constant direction in which the light emitting element emits the light, the light emitting element can efficiently emit the light with less power consumption.

According to the present invention, the voltage is applied to the light emitting element such that the current does not flow in the dielectric layer in the direction in which the light is not substantially emitted, so that the power outputted from the drive power supply is prevented from being converted to heat, and the light emitting element can be prevented from generating heat.

### BRIEF DESCRIPTION OF THE DRAWINGS

FIG. 1 is an explanatory diagram showing a configuration of a light emitting device according to one embodiment of the present invention.

FIGS. 2(a) to (d) are schematic cross-sectional views showing configurations of light emitting elements included in the light emitting device according to each one embodiment of the present invention.

FIGS. 3(a) to (c) are circuit diagrams showing power supply circuits in which drive power supplies apply voltages to the light emitting elements included in the light emitting device according to each one embodiment of the present invention.

FIG. 4 is a fabricating flowchart of a light emitting element fabricated in an EL experiment.

FIG. 5 is a light emission spectrum of the light emitting element fabricated in the EL experiment.

FIG. 6 is a graph showing I-V characteristics and light emission-voltage characteristics of the light emitting element fabricated in the EL experiment.

FIG. 7 is a graph showing light emission time characteristics of the light emitting element fabricated in the EL experiment.

FIG. 8 is a graph showing a relationship between a heat treatment temperature and light emission intensity of the light emitting element fabricated in the EL experiment.

FIG. 9 is a graph showing a relationship between a germanium concentration and the light emission intensity of the light emitting element fabricated in the EL experiment.

FIG. 10 is an XPS spectrum measured at each depth from a surface of a silicon oxide film of the light emitting element fabricated in the EL experiment.

FIG. 11 is a graph showing a relationship between a depth from the surface of the silicon oxide film and a ratio of Ge⁰, Ge²⁺, and Ge⁴⁺ of the light emitting element fabricated in the EL experiment.

### EMBODIMENTS OF THE INVENTION

A light emitting device according to the present invention comprises: a light emitting element including a semiconductor layer, a first electrode, a dielectric layer sandwiched between the semiconductor layer and the first electrode, and a light emitter; and a power supply circuit for applying a voltage between the semiconductor layer and the first electrode, wherein the light emitter is formed in at least one region of regions in the semiconductor layer, in the dielectric layer, between the semiconductor layer and the dielectric layer, and between the first electrode and the dielectric layer, the light emitting element emits light in one of first and second cases, but does not substantially emit light in the other case, the first case using a current applied to the dielectric layer under a condition that the semiconductor layer serves as a positive electrode and the first electrode serves as a negative electrode, the second case using a current applied to the dielectric layer under a condition that the semiconductor layer serves as the negative electrode and the first electrode serves as the positive electrode, and the power supply circuit is electrically connected to each of the semiconductor layer and the first electrode so that a unidirectional current flows in the dielectric layer while the light emitting element emits the light.

Preferably, in the light emitting device of the present invention, the light emitting element is higher in electric resistance in a case where the current flows in the dielectric layer while the light emitting element emits the light than in a case where the current flows in the dielectric layer while the light emitting element does not emit the light.

According to this configuration, the light emitting element can emit the light with less power consumption.

Preferably, in the light emitting device of the present invention, the power supply circuit comprises a rectifying diode to apply the current to the dielectric layer provided between the semiconductor layer and the first electrode, and the power supply circuit is supplied with a power from an AC power supply.

According to this configuration, even when the AC power supply is used as the drive power supply, the voltage can be applied to the light emitting element so that the unidirectional current flows in the dielectric layer.

Preferably, in the light emitting device of the present invention, the power supply circuit is supplied with a power from a DC power supply.

According to this configuration, the voltage can be applied to the light emitting element so that the unidirectional current flows in the dielectric layer.

Preferably, in the light emitting device of the present invention, the semiconductor layer is made of an n-type semiconductor or a p-type semiconductor, and the power supply circuit is electrically connected to each of the semiconductor layer and the first electrode so that the semiconductor layer serves as the positive electrode and the first electrode serves as the negative electrode when the semiconductor layer is made of the n-type semiconductor, while the power supply circuit is electrically connected to each of the semiconductor layer and the first electrode so that the semiconductor layer serves as the negative electrode and the first electrode serves as the positive electrode when the semiconductor layer is made of the p-type semiconductor.

According to this configuration, when the voltage is applied to the light emitting element so that the unidirectional current flows in the dielectric layer, the light emitting element can emit the light.

Preferably, in the light emitting device of the present invention, the light emitter comprises germanium atoms.

According to this configuration, the light emitting element can emit the light.

Preferably, in the light emitting device of the present invention, the light emitter comprises ZnS.

According to this configuration, the light emitting element can emit the light.

Preferably, in the light emitting device of the present invention, the light emitting element has a surface temperature of 60° C. or lower in the case where the current flows in the dielectric layer while the light emitting element emits the light.

According to this configuration, even when the light emitting element is mounted on an opto-electronic circuit, the heat generation of the light emitting element can be prevented from affecting another element. In addition, even when the light emitting element is used for a light source such as illumination, the heat generation of the light emitting element can be prevented from being involved in deterioration in brightness.

Hereinafter, one embodiment of the present invention will be described with reference to the drawings. Configurations shown in the drawings and the following description are illustrative and the scope of the present invention is not limited to those described in the drawings and the following description.

### Configuration of Light Emitting Device

FIG. 1 is an explanatory diagram showing a configuration of a light emitting device according to one embodiment of the present invention. In FIG. 1, a light emitting element 12 is shown with a schematic cross-sectional view, and a drive power supply 15 and a power supply circuit for applying a voltage to the light emitting element 12 are shown with circuit diagrams.

A light emitting device 20 according to this embodiment comprises: a light emitting element 12 including a semiconductor layer 1, a first electrode 7, a dielectric layer 3 sandwiched between the semiconductor layer 1 and the first electrode 7, and a light emitter 5; and a power supply circuit 13 for applying a voltage between the semiconductor layer 1 and the first electrode 7, wherein the light emitter 5 is formed in at least one region of regions in the semiconductor layer 1, in the dielectric layer 3, between the semiconductor layer 1 and the dielectric layer 3, and between the first electrode 7 and the dielectric layer 3, the light emitting element 12 emits light in one of first and second cases, but does not substantially emit light in the other case, the first case using a current applied to the dielectric layer 3 under a condition that the semiconductor layer 1 serves as a positive electrode and the first electrode 7 serves as a negative electrode, the second case using a current applied to the dielectric layer 3 under a condition that the semiconductor layer 1 serves as the negative electrode and the first electrode 7 serves as the positive electrode, and the power supply circuit 13 is electrically connected to each of the semiconductor layer 1 and the first electrode 7 so that a unidirectional current flows in the dielectric layer 3 while the light emitting element 12 emits the light.

Hereinafter, the light emitting device 20 in this embodiment will be described.

### 1. Light Emitting Element

The light emitting element 12 includes the semiconductor layer 1, the first electrode 7, the dielectric layer 3 sandwiched between the semiconductor layer 1 and the first electrode 7, and the light emitter 5. In addition, the light emitter 5 is formed in at least one region of regions in the semiconductor layer 1, in the dielectric layer 3, between the semiconductor layer 1 and the dielectric layer 3, and between the first electrode 7 and the dielectric layer 3. In addition, the light emitting element 12 emits light in one of first and second cases, but does not substantially emit light in the other case, the first case using a current applied to the dielectric layer 3 under a condition that the semiconductor layer 1 serves as a positive electrode and the first electrode 7 serves as a negative electrode, the second case using a current applied to the dielectric layer 3 under a condition that the semiconductor layer 1 serves as the negative electrode and the first electrode 7 serves as the positive electrode. In addition, according to this application, the current flowing in the dielectric layer 3 in the case where the light emitting element 12 emits the light is referred to as a “current accompanied with the light emission”, and the current flowing in the dielectric layer 3 in the case where the light emitting element 12 does not substantially emit the light is referred to as a “current not accompanied with the light emission”. The light emitting element 12 may be an inorganic EL element. In addition, the term “the light emitting element 12 does not substantially emit light” includes a case where the light emitting element 12 does not emit the light even when the current flows in the dielectric layer 3, and a case where an emitted light amount provided when the “current not accompanied with the light emission” flows in the dielectric layer 3 is sufficiently small compared with an emitted light amount provided when “the current accompanied with the light emission” flows therein.

The light emitting element 12 may have high electric resistance in the case where the current accompanied with the light emission flows in the dielectric layer 3, compared with the case where the current not accompanied with the light emission flows in the dielectric layer 3. In this case, in a case where the same voltage is applied between the semiconductor layer 1 and the first electrode 7 with polarities reversed, a magnitude of the “current not accompanied with the light emission” is greater than a magnitude of the “current accompanied with the light emission”. In addition, when it is assumed that a light emission voltage threshold represents −Vₐ, and a current value at this time represents −I₁, a current value +I₂ when a voltage of +Vₐ is applied can be |I₂|>10×|I₁|.

According to a light emission mechanism of the light emitting element 12, it is considered that an electric field is formed in the dielectric layer 3 and the semiconductor layer 1 by a voltage applied between the semiconductor layer 1 and the first electrode 7, electrons introduced from the semiconductor layer 1 or the first electrode 7 to the dielectric layer 3 are accelerated by the electric field, and the accelerated electrons excite the light emitter 5 and its excited level is relaxed, whereby the light emitter 5 emits the light.

### 2. Semiconductor Layer

The semiconductor layer 1 is provided so as to sandwich the dielectric layer 3 with the first electrode 7, and can serve as an electrode for applying the voltage from the drive power supply 15 to the dielectric layer 3. The semiconductor layer 1 is not limited in particular as long as it is made of a semiconductor which can serve as the electrode, and it may be a p-type semiconductor or an n-type semiconductor, for example. As for many semiconductor materials, their resistivity can be adjusted by impurity doping. In addition, when the light emitting element 12 is mounted on an opto-electronic substrate, it is to be configured as a discrete element to be provided on the semiconductor substrate without being bonded, because it is thought that there is a merit in an aspect such as an occupied area.

The semiconductor layer 1 may have both of the p-type semiconductor and the n-type semiconductor on a surface which is in contact with the dielectric layer 3. In addition, the semiconductor layer 1 may be a semiconductor layer formed on the substrate, may be a semiconductor substrate, or may be a part of the semiconductor substrate. More specifically, it can be a p-type silicon substrate or an n-type silicon substrate, for example. In addition, it may be provided by forming p-type silicon or n-type silicon on a SiO₂ substrate, or forming the dielectric layer 3 of SiO₂ on a Si substrate and forming p-type silicon or n-type silicon thereon. In this case, the light emitting element 12 may be formed on a crystal silicon substrate included in a SOI (Silicon On Insulator) substrate, or amorphous silicon is formed on the dielectric layer 3 of SiO₂ by CVD, and the light emitting element 12 may be formed thereon.

### 3. First Electrode

The first electrode 7 is provided to sandwich the dielectric layer 3 with the semiconductor layer 1, and can serve as an electrode for applying the voltage from the drive power supply to the dielectric layer 3. The first electrode 7 is not limited in particular as long as it serves as the electrode, but it preferably has translucency. The first electrode 7 can be a translucent electrode, for example. In addition, transmittance of the first electrode 7 for light having a wavelength between 300 nm and 500 nm may be 60% to 99.99%. Thus, the light emitted from the light emitter 5 can be taken out from a side of the first electrode. The first electrode 7 is a metal oxide thin film of ITO, a metal thin film of Al, Ti, or Ta, or a semiconductor thin film of Si, SiC, or GaN, for example.

### 4. Dielectric Layer

The dielectric layer 3 is provided so as to be sandwiched between the semiconductor layer 1 and the first electrode 7. For example, the dielectric layer 3 is made of silicon oxide, silicon nitride, or silicon oxynitride. In addition, since the film can be formed of silicon oxide, silicon nitride, or silicon oxynitride by a general silicon semiconductor process, its productivity is great and it can be combined with another electronic circuit. In addition, when it is assumed that the dielectric layer 3 is made of silicon oxide, and the semiconductor layer 1 is the silicon substrate, the dielectric layer 3 can be a thermally-oxidized film of the silicon substrate, so that it can be easily formed.

A thickness of the dielectric layer 3 is between 10 nm and 100 nm (a range between any two of 10, 20, 30, 40, 50, 60, 70, 80, 90, and 100 nm, for example).

The dielectric layer 3 can have translucency. In this case, the light emitted from the light emitter 5 can be extracted. Light transmittance of the dielectric layer 3 for light having a wavelength of 300 to 500 nm is preferably 80% or higher. In a case where the light emitter 5 is composed of fine particles containing GeO and GeO₂, a peak wavelength of the light emitted from the light emitter 5 is around 390 nm, if the transmittance of the light with the wavelength of 300 to 500 nm is high, a light extraction efficiency is heightened correspondingly.

### 5. Light Emitter

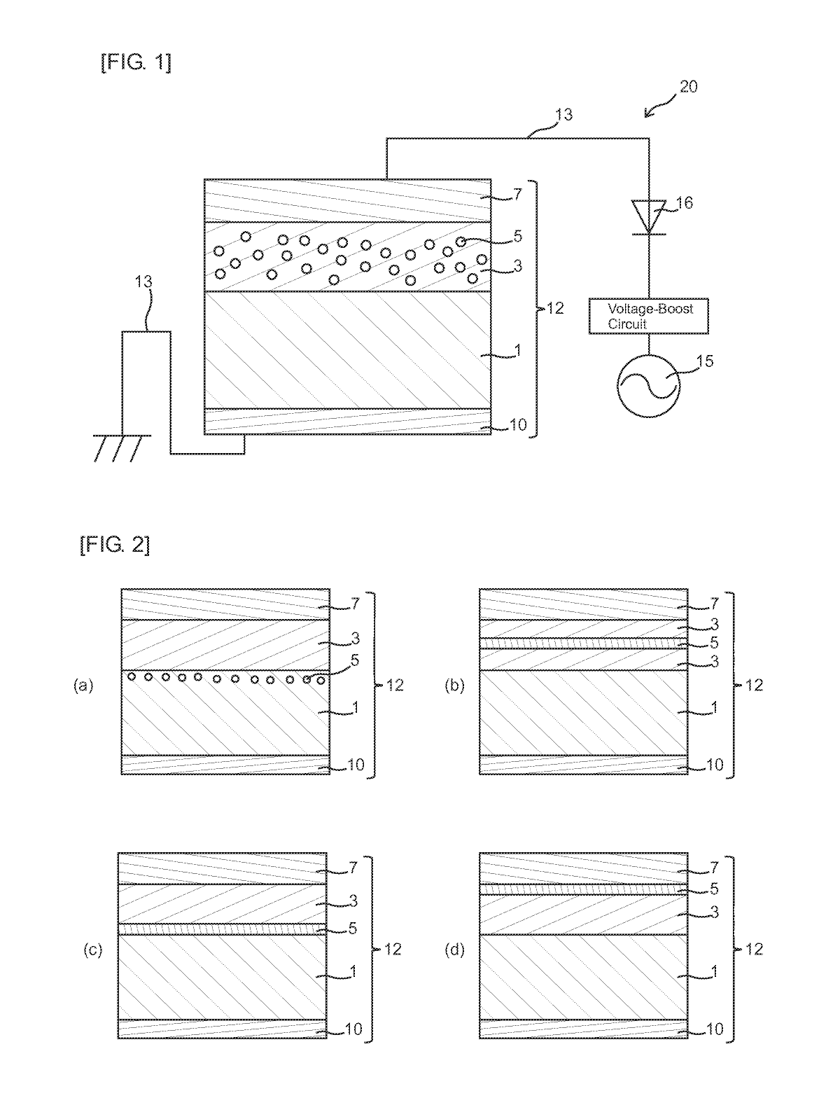

The light emitter 5 is formed in at least one region of regions in the semiconductor layer 1, in the dielectric layer 3, between the semiconductor layer 1 and the dielectric layer 3, and between the first electrode 7 and the dielectric layer 3. FIG. 2 shows cross-sectional views of the light emitting elements 12 in various embodiments. The light emitter 5 may be formed in the dielectric layer 3 as shown in FIG. 1, or may be formed in the semiconductor layer 1 as shown in FIG. 2(a). In addition, the light emitter 5 may exist in the semiconductor layer 1 or in the dielectric layer 3 as atoms, or exist therein as fine particles. In addition, the light emitter 5 may be formed in a shape of a layer as shown in each of FIG. 2(b) to (d). The layer-shaped light emitter 5 may be formed so as to be sandwiched between the dielectric layers 3 as shown in FIG. 2(b), may be formed between the semiconductor layer 1 and the dielectric layer 3 as shown in FIG. 2(c), or may be formed between the dielectric layer 3 and the first electrode 7 as shown in FIG. 2(d).

The atom of the light emitter 5 includes germanium atom, silicon atom, or tin atom, and it can be formed by implanting ions of the germanium atoms or the like into the dielectric layer 3 made of silicon oxide. The fine particle of the light emitter 5 includes germanium fine particle, for example. In addition, the layer-shaped light emitter 5 includes a layer made of ZnS.

Hereinafter, the case where the light emitter 5 is made of germanium fine particles will be described.

The germanium fine particles can be formed by implanting ions of the germanium atoms into the dielectric layer 3 made of silicon oxide and aggregating the germanium atoms through a heat treatment, for example. In this case, the formed germanium particles may be subjected to a heat treatment to become germanium fine particles containing a germanium oxide. Furthermore, the germanium atom contained in the germanium oxide may be divalent or quadrivalent, or the divalent germanium atom (hereinafter, referred to as Ge²⁺) and the quadrivalent germanium atom (hereinafter, referred to as Ge⁴⁺) may be mixed. In addition, a number density of an atom composing the light emitter 5 in the dielectric layer 3 is, for example, 1×10¹⁶/cm³ to 1×10²¹/cm³.

The light emitter 5 is preferably a fine particle having a maximum particle diameter between 1 nm and 20 nm. It is because light emission efficiency is particularly heightened in this case. In the present invention, the “maximum particle diameter” means a diameter of the fine particle whose diameter is maximum among the fine particles which can be observed when a TEM observes a range of 100 nm square in a certain cross-sectional surface (which may be a cross-sectional surface shown in FIG. 1, or a cross-sectional surface vertical to sheet surface) of the dielectric layer 3. Furthermore, in the present invention, the “particle diameter” means a length of a longest line which can be contained in a planar image of the fine particle taken in a TEM photograph when viewed in a cross-sectional TEM photograph. The maximum particle diameter of the fine particle is 1, 2, 3, 4, 5, 6, 7, 8, 9, 10, 12, 14, 16, 18, or 20 nm, for example. The maximum diameter of the fine particle may be in the range between whichever two numerals exemplified above and may be whichever one numeral value or lower.

A ratio of Ge²⁺ to an entire germanium oxide (Ge⁴⁺+Ge²⁺) can be determined by measuring peak surface area S_{Ge4+} attributed to Ge⁴⁺ and peak surface area S_{Ge2+} attributed to Ge²⁺ in a spectrum near 3d peak of Ge of XPS spectrum, and calculating S_{Ge2+}/(S_{Ge4+}+S_{Ge2+}). As an X-ray source for the XPS measurement, Al, K-α ray (1486.6 eV) made monochromatic can be employed, for example. The peak attributed to Ge⁴⁺ and the peak attributed to Ge²⁺ are overlapped in skirt parts; however Gaussian-fitting may be carried out to separate a waveform of the peak attributed to Ge⁴⁺ and the peak attributed to Ge²⁺ and thus the surface areas S_{Ge4+} and S_{Ge2+} can be measured. Peak energies of Ge⁴⁺ and Ge²⁺ are about 33.5 eV and 32 eV, respectively.

In the case where the light emitter 5 is the germanium fine particles containing Ge²⁺ and Ge⁴⁺, the light emitter 5 can contain 10% or more of Ge²⁺ when assuming that a total of Ge²⁺ and Ge⁴⁺ is 100%. When the ratio of Ge²⁺ is too small, the emission may sometimes be impossible or emission intensity may become too low. More specifically, the ratio of Ge²⁺ is 10, 20, 30, 40, 50, 60, 70, 80, 90, 95, 99, or 100%, for example. The ratio of Ge²⁺ may be in a range of whichever two numeral values exemplified herein.

By the way, in the spectrum near 2p peak of Ge of the XPS spectrum, an oxidation rate of Ge can be determined by measuring peak surface area S_{Ge} attributed to zero-valent germanium (hereinafter, referred to as Geo) and peak surface area S(oxidation)_{Ge} attributed to germanium oxide (Ge²⁺ and Ge⁴⁺), and calculating S_{Ge2+}/(S_{Ge}+S(oxidation)_{Ge}). An average value of the oxidation rate is not limited in particular, and it is 1, 5, 10, 15, 20, 25, 30, 34.9, 35, 40, 45, 50, 55, 60, 60.1, 65, 70, 70.1, 75, 80, 85, 90, 95, 99, or 100%, for example. The average value of this oxidation rate may be in a range of whichever two numeral values exemplified herein.

As for the light emitting element 12 in which the light emitter 5 is composed of the germanium fine particles formed in the dielectric layer 3, a peak of a wavelength of electroluminescence (EL) when a voltage is applied between the semiconductor layer 1 and the first electrode 7 falls within a range of 340 to 440 nm (more strictly, 350 to 430 nm, 360 to 420 nm, 370 to 410 nm, 380 to 400 nm, or 385 to 395).

### 6. Second Electrode

A second electrode 10 is formed to be electrically connected to the semiconductor layer 1. The semiconductor layer 1 can be connected to the drive power supply 15 through the second electrode. Alternatively, the semiconductor layer 1 can be connected to the ground through the second electrode. The second electrode 10 can be a metal electrode such as an aluminum electrode, for example.

### 7. Drive Power Supply and Power Supply Circuit

The drive power supply 15 applies the voltage between the semiconductor layer 1 and the first electrode 7 so that a unidirectional current flows in the dielectric layer 3 while the light emission element 12 emits the light. A power outputted from the drive power supply 15 is supplied to the light emitting element 12 through the power supply circuit 13. The drive power supply 15 may be a DC power supply or an AC power supply as long as a direction of the current flowing in the dielectric layer 3 is constant. In addition, in the case where the drive power supply 15 is the AC power supply, a rectifying diode 16 may be included in the power supply circuit 13 used when the drive power supply 15 applies the voltage to the dielectric layer 3. In this case, power supply having an opposite polarity is converted and a voltage having a desired polarity can be outputted. In addition, a voltage-boost circuit or a voltage-drop circuit may be included in the power supply circuit 13 used when the drive power supply 15 applies the voltage to the dielectric layer 3. In this case, the output of the drive power supply 15 can be converted to a desired voltage value and outputted to the light emitting element 12.

In addition, in the present invention, the “unidirectional current” means a current in which a current value is increased as an applied voltage is increased and a current flow direction is constant.

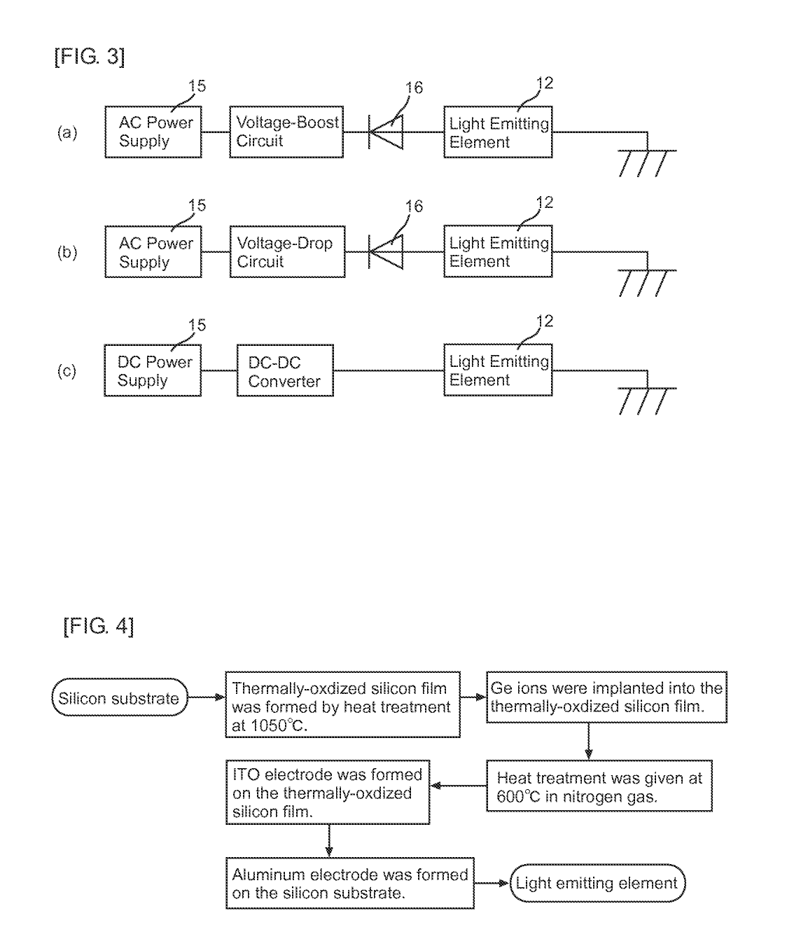

In the case where the drive power supply 15 is the AC power supply, the drive power supply may be a power supply which outputs a voltage having a desired waveform. The drive power supply 15 may output a square-wave voltage, or may output a sine-wave voltage. FIGS. 3(a) to (c) are circuit diagrams showing various power supply circuits 13 through which the voltage is outputted from the drive power supply 15 to the light emitting element 12. For example, as shown in FIG. 3(a), the drive power supply 15 may be a low-voltage sine-wave AC power supply which is electrically connected to the light emitting element 12 with the voltage-boost circuit and the rectifying diode 16 provided between the drive power supply 15 and the light emitting element 12. The voltage-boost circuit changes the voltage outputted from the drive power supply 15 to a desired voltage value, and the rectifying diode 16 can output only a half wave to the light emitting element 12. Thus, the current flowing in the constant direction can be applied to the light emitting element 12. By conforming the direction of this current to the direction of the current accompanied with the light emission of the light emitting element, the light emitting element can emit the light.

In addition, as shown in FIG. 3(b), the drive power supply 15 may be the AD power supply which is electrically connected to the light emitting element 12 with the voltage-drop circuit and the rectifying diode 16 provided between the drive power supply 15 and the light emitting element 12, for example. The voltage-drop circuit changes the voltage outputted from the drive power supply 15 to a desired voltage value, and the rectifying diode 16 can output only the half wave to the light emitting element 12.

In addition, as shown in FIG. 3(c), the drive power supply 15 may be the DC power supply which is electrically connected to the light emitting element 12 with a DC-DC converter provided between the drive power supply 15 and the light emitting element 12, for example. The DC-DC converter can convert the voltage outputted from the drive power supply 15 to a desired voltage value, and output it to the light emitting element 12.

### Method for Fabricating Light Emitting Element

Hereinafter, a description will be given of a method for fabricating the light emitting element 12 when the light emitter 5 is composed of the germanium fine particles.

### 1. Formation of Semiconductor Layer

In a case where as the semiconductor layer 1, the p-type silicon substrate or the n-type silicon substrate is used, this can serve as the semiconductor layer 1. Alternatively, the semiconductor layer 1 may be formed in a part of the silicon substrate by diffusing a p-type impurity or an n-type impurity in the silicon substrate.

### 2. Formation of Dielectric Layer

The dielectric layer 3 is formed on the semiconductor layer 1. For example, the dielectric layer 3 can be formed of silicon oxide by performing a heat treatment on the silicon substrate, or the dielectric layer 3 can be formed by depositing a silicon oxide or a silicon nitride by CVD or sputtering.

### 3. Formation of Light Emitter

The light emitter 5 is formed in the dielectric layer 3. A method for forming the light emitter 5 in the dielectric layer 3 is not limited in particular, but as a conceivable method, germanium ions are implanted into the dielectric layer 3, and then a heat treatment is performed. The germanium ions are aggregated by the heat treatment after the ion implantation and many fine particles are formed in the dielectric layer, and Ge⁰ is oxidized and the germanium oxides including Ge²⁺ and Ge⁴⁺ are formed. The ion implantation of germanium can be performed under a condition that an implantation energy is set to 5 to 100 keV, and an implantation amount is 1×10¹⁴ to 1×10¹⁷ ions/cm².

The ratio of Ge²⁺ and Ge⁴⁺ can be appropriately adjusted by changing the implantation amount of germanium, a heat treatment time, a heat treatment temperature, a heat treatment atmosphere, or the like. More specifically, by adjusting a partial pressure and a flow rate of oxygen in the heat treatment atmosphere, the ratio of Ge²⁺ can be increased. For example, in a case where an atomic concentration of germanium in the silicon oxide with a film thickness of 100 nm is 10% or lower, when an inert gas is supplied (50 mL per minute) while vacuum evacuation is carried out (400 L per minute) in a heat treatment for one hour at 800° C., germanium is partially combined with oxygen, but not completely oxidized because oxygen is insufficient, and Ge²⁺ can be formed. In an atmosphere having one atmospheric pressure in which 20% by volume of oxygen is mixed in the inert gas, an amount of Ge⁴⁺ is increased and an amount of Ge²⁺ is reduced because oxygen is supplied too much. An atmosphere suitable to increase the ratio of Ge²⁺ is influenced by other parameters such as germanium implantation condition, and the heat treatment time and temperature, but as one example, the ratio of Ge²⁺ can be increased by setting the atomic concentration of germanium relatively high, and supplying a gas in which the oxygen is mixed to the inert gas while vacuum evacuation is carried out.

In addition, the ion implantation of germanium is preferably performed so that the germanium concentration in the dielectric layer 3 reaches 0.1 to 10.0% by atom. This is because in a case where the inert gas is supplied (50 mL per minute) while vacuum evacuation is carried out (400 L per minute) in a heat treatment for one hour at 600° C., light emission efficiency can be relatively high in this range. More specifically, the germanium concentration is 0.1, 0.2, 0.3, 0.4, 0.5, 0.6, 0.7, 0.8, 0.9, 1.0, 2.0, 3.0, 4.0, 5.0, 6.0, 7.0, 8.0, 9.0, or 10.0% by atom. This concentration may be in a range of whichever two numeral values exemplified herein. The germanium concentration can be measured by a high-resolution RBS (Rutherford back scattering) method. In addition, it can be measured by various analysis methods such as SIMS (secondary ion mass spectrometry). In addition, the germanium concentration is measured to the extent that the germanium concentration reaches 1/100 or more of a peak value. A temperature of the heat treatment is preferably 400 to 900° C., and more preferably 500 to 800° C. This is because the light emission efficiency is relatively high in this range.

### 4. Formation of First Electrode

A translucent electrode serving as the first electrode 7 is formed on the dielectric layer 3 in which the light emitter 5 is formed. For example, when it is an ITO electrode, it can be formed by coating, sputtering, or the like.

### 5. Formation of Second Electrode

The second electrode 10 is formed so as to be electrically connected to the semiconductor layer 1. A method for forming the second electrode is not limited in particular, and an aluminum electrode, for example, can be formed on the semiconductor layer 1 by coating, sputtering, or the like.

### EL Experiment

### 1. Effect Confirming Experiment

An experiment was performed to confirm the effect of the light emitting device in the present invention by a following method. FIG. 4 is a flowchart of a method for fabricating the light emitting element 12.

First, an n-type silicon substrate having an impurity concentration of 5×10¹⁵ cm⁻³ was thermally oxidized in an oxygen atmosphere at 1050° C., whereby a thermally-oxidized silicon film of 60 nm was formed on its surface.

Then, Ge ions were implanted into the thermally-oxidized silicon film under a condition of 9.2×10¹⁵ ions/cm² at 50 keV.

Then, the silicon substrate in which the thermally oxidized film was formed was set in an electric furnace, and subjected to a heat treatment at 600° C. for one hour while vacuuming was performed by a rotary pump and nitrogen was introduced.

Then, an ITO electrode was formed on the thermally-oxidized silicon film, and an aluminum electrode was formed on a side of the silicon substrate, whereby a light emitting element used for an EL experiment was obtained.

The fabricated EL element has a cross-sectional surface like a cross-sectional view of the light emitting element 12 shown in FIG. 1.

Under a condition that the aluminum electrode of this light emitting element was connected to the ground, when a voltage was applied to the thermally-oxidized silicon film (dielectric layer 3) with the n-type silicon substrate (semiconductor layer 1) serving as the positive electrode and the ITO electrode (first electrode 7) serving as the negative electrode while ITO electrode was at about −40 V, it was confirmed that blue light was emitted.

As for the above EL element, the n-type silicon substrate was used as the semiconductor layer 1, so that when the negative voltage was applied between the ITO electrode and the silicon substrate, the light was emitted. In the case where the p-type silicon substrate is used as the semiconductor layer 1, when the positive voltage is applied between the ITO electrode and the silicon substrate, the light is emitted.

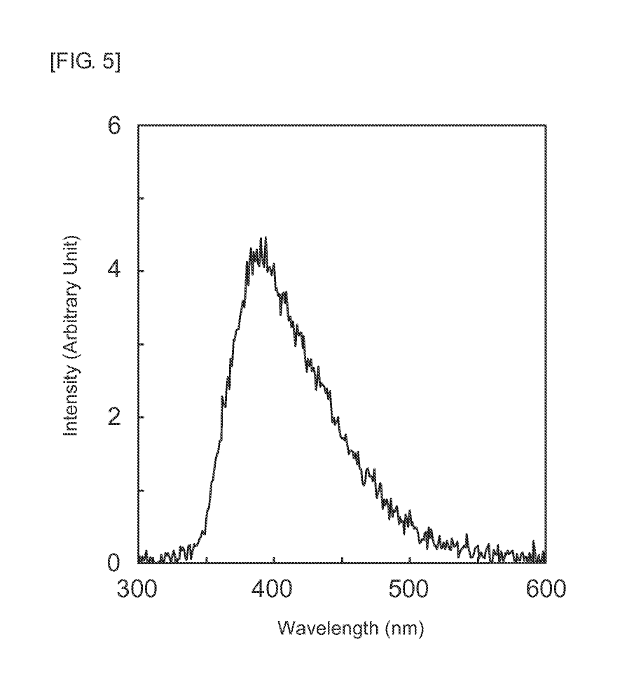

In addition, FIG. 5 shows a light emission spectrum of the blue light of the fabricated EL element. Referring to FIG. 5, it is found that the confirmed blue emitted light is electroluminescence light having a wavelength of 340 nm to 550 nm, and a peak between 340 nm and 440 nm.

In addition, with an n-type silicon substrate and a p-type silicon substrate each having an impurity concentration of 1.0×10¹⁷ cm⁻³, light emitting elements were fabricated by the same method, respectively, and a voltage was applied between the silicon substrate and the ITO electrode, but light emission was not confirmed. Furthermore, with a p-type silicon substrate having an impurity concentration of 5×10¹⁵ cm⁻³, a light emitting element was fabricated by the same method, and when a voltage was applied between the silicon substrate and the ITO electrode, light emission was confirmed.

As a result, it has been found that the light emitting element can emit the electroluminescence light by fabricating the light emitting element with the silicon substrate having the impurity concentration of 5×10¹⁵ cm⁻³ or less.

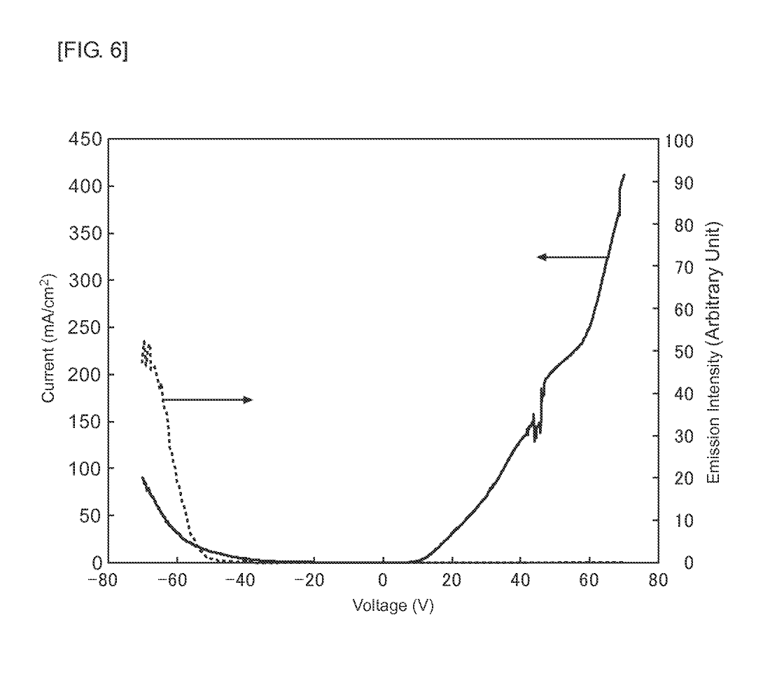

The aluminum electrode of the fabricated EL element was connected to the ground, and a potential of the ITO electrode was changed between −70 V and +70 V, and I-V characteristics and light emission-voltage characteristics of the EL element were measured. FIG. 6 shows a result of this measurement. Referring to FIG. 6, it is found that in a case where a voltage is applied so that the ITO electrode has the negative potential, when the current flows in the EL element, the EL element emits light, and in a case where a voltage is applied so that the ITO electrode has the positive potential, even when the current flows in the EL element, the EL element hardly emits light. In addition, it is found that in a case where a voltage having the same potential difference is applied to the EL element, when comparing the case where the ITO electrode has the negative potential to the case where the ITO electrode has the positive potential, a current having a larger current value flows in the EL element in the case where the ITO electrode has the positive potential. That is, it is found that in the case where the current accompanied with the light emission flows in the EL element (the case where the ITO electrode has the negative potential, that is, the case where the voltage is applied with the silicon substrate serving as the positive electrode and the ITO electrode serving as the negative electrode), an electric resistance value of the EL element is large and power consumption is small, compared with the case where the current not accompanied with the light emission flows in the EL element (the case where the ITO electrode has the positive potential, that is, the case where the voltage is applied with the silicon substrate serving as the negative electrode and the ITO electrode serving as the positive electrode).

In addition, referring to FIG. 6, it is found that the light emission voltage threshold −Vₐ of the EL element is −40 V, and the current value −I₁ at this time is −4.3 mA/cm². At this time, a current value +I₂ when the voltage of +Vₐ 40 V having an opposite sign of the light emission threshold is applied to the EL element is 126 mA/cm². This satisfies the condition that |I₂|>10×|I₁| described above in this specification. That is, it is found that the current which does not contribute the light emission largely flows in the EL element when the sine-wave voltage is applied to the EL element and the ITO electrode have the positive potential.

Next, a surface temperature of the EL element at the time of the voltage application was measured. More specifically, a type-k thermocouple wrapped with a thin polyimide tape was attached to the aluminum electrode surface connected to the ground in the fabricated EL element, the drive power supply was connected to the ITO electrode, the voltage was applied to the EL element at 25° C. by each of methods 1 to 8 described in table 1, and the surface temperature of the EL element was measured. The reason why the thermocouple was wrapped with the polyimide tape is to prevent the current flowing in the EL element at the time of the voltage application from affecting the temperature measurement.

A result of this measurement is shown in table 1. An element temperature shown in table 1 is provided by calculating a measurement average value for 100 seconds after the voltage has been applied by each method and the element temperature has reached its saturated state.

TABLE 1

| | | | | Element |
|---|---|---|---|---|
| Voltage | | | | Surface |
| Application | | Maximum | Minimum | Temperature |
| Method | Waveform | Voltage (V) | Voltage (V) | (° C.) |
| Method 1 | Square Wave, | +60 | −60 | 86 |
| | duty 50% | | | |
| Method 2 | Square Wave, | +60 | 0 | 70 |
| | duty 50% | | | |
| Method 3 | Square Wave, | 0 | −60 | 31 |
| | duty 50% | | | |
| Method 4 | Sine Wave | +60 | −60 | 49 |
| Method 5 | Direct Current | −60 | | 35 |
| Method 6 | Direct Current | +60 | | 115 |
| Method 7 | Square Wave, | +60 | −60 | 55 |
| | duty 20% | | | |
| Method 8 | Square Wave, | +60 | −60 | 107 |
| | duty 80% | | | |

According to the voltage application methods 1 to 3 in table 1, each shows an element surface temperature when the square-wave voltage is applied to the EL element, and a maximum voltage and a minimum voltage are different from each other.

It has been found that according to the voltage application methods 1 and 2, the element surface temperature is 70° C. or more, while according to the voltage application method 3, the element surface temperature is as low as about 30° C. According to the voltage application methods 1 and 2, since the maximum voltage is +60 V, the ITO electrode serves as the positive electrode and the silicon substrate serves as the negative electrode, so that the current (current not accompanied with the light emission) flows in the thermally-oxidized film, but according to the voltage application method 3, since the maximum voltage is 0 V, it is considered that the “current not accompanied with the light emission” does not flow. Therefore, it has been found that when the “current not accompanied with the light emission” flows, an amount of heat generation of the EL element is large. In addition, it has been found that when the voltage is applied to the EL element such that this “current not accompanied with the light emission” will not flow, the heat generation of the EL element can be suppressed.

In addition, according to the voltage application methods 1 and 3, since the minimum voltage is −60 V, the ITO electrode serves as the negative electrode and the silicon substrate serves as the positive electrode, so that the current (“current accompanied with the light emission”) flows in the thermally-oxidized film, but according to the voltage application method 2, since the minimum voltage is 0 V, it is considered that the “current accompanied with the light emission” does not flow. According to the voltage application method 3, the element surface temperature is as low as 30° C., and according to the voltage application method 1, the voltage is only higher by 15° C. than the voltage application method 2. Therefore, it has been found that even when the “current accompanied with the light emission” flows, the amount of heat generation of the EL element is small.

According to the voltage application method 4 in table 1, it shows an element surface temperature when the sine-wave voltages of a maximum voltage +60 V and a minimum voltage −60 V are applied to the EL element. Compared with the voltage application method 1 in which the maximum voltage and the minimum voltage are the same, the temperature rise is suppressed to be lower in the voltage application method 4. It is considered that this is because the applied voltage in the voltage application method 4 is the sine wave, so that the “current not accompanied with the light emission” is small.

According to the voltage application methods 5 and 6 shown in table 1, each shows an element surface temperature when a DC voltage is applied to the EL element so that the ITO electrode reaches −60 V or +60 V. According to the voltage application method 5, the element surface temperature is as low as 35° C. It is considered that this is because the voltage is applied so that the ITO electrode reaches −60 V, so that the “current accompanied with the light emission” flows, but the “current not accompanied with the light emission” does not flow. According to the voltage application method 6, the element surface temperature is as high as 115° C. It is considered that this is because the voltage is applied so that the ITO electrode reaches +60 V, so that the “current accompanied with the light emission” flows a lot, but the “current not accompanied with the light emission” does not flow.

According to the voltage application methods 7 and 8 in table 1, each shows an element surface temperature when square-wave voltages of a maximum voltage +60 and a minimum voltage −60V which are symmetrical with respect to 0 V to be positive and negative are applied to the EL element with a duty ratio changed. Here, the duty ratio means (application time of positive voltage)/(application time of positive voltage+application time of negative voltage). From the above results, it has been found that as the application time of the positive voltage is increased, the element surface temperature is increased.

To summarize the above, it has been found that as for the fabricated EL elements, when only the negative voltage is applied, the heat generation can be suppressed to be small without regard to its waveform, but when the positive voltage is applied a little, the heat generation is immediately increased. Especially, in the case of the opto-electronic circuit, the LSI and the light emitting element are closely provided, and the LSI is strongly influenced by temperature, so that the heat generation is preferably small. As one target, the element surface temperature is preferably suppressed to be 85° C. or lower. This temperature 85° C. is one target for reliability of the LSI or the like. In addition, the element surface temperature is preferably suppressed to be 60° C. or lower.

In order to suppress the element surface temperature, it is preferable that the drive power supply only applies the voltage having the polarity to the light emitting element. In order to attain this configuration, the drive power supply is to be composed of the DC power supply, or the AC power supply having the diode provided in a supply line.

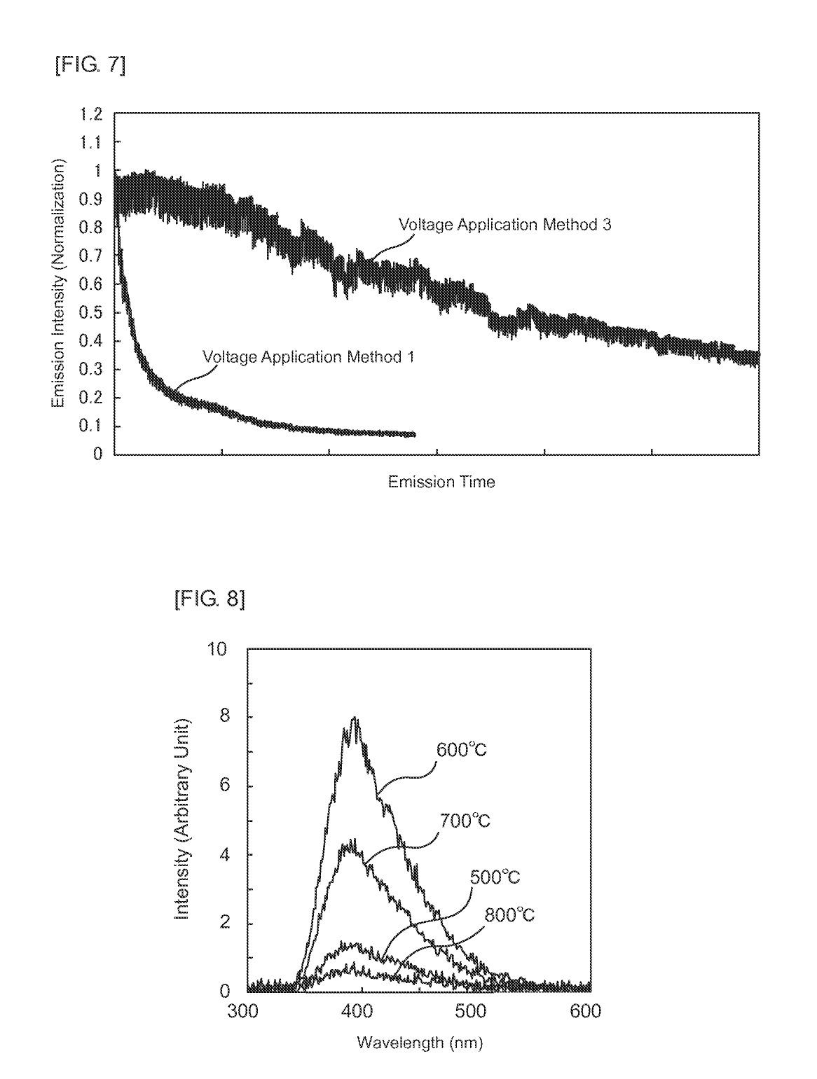

Next, a light emitting time was measured when the voltage was applied to the EL element by each of the voltage application method 1 (square wave, maximum voltage=+60 V, minimum voltage=−60 V) and the voltage application method 3 (square wave, maximum voltage=0 V, minimum voltage=−60 V). A result of this is shown in FIG. 7. Referring to FIG. 7, it is found that deterioration in light emission intensity is less in the case where the voltage is applied to the EL element by the voltage application method 3, than the case where the voltage is applied to the EL element by the voltage application method 1. When a time until the intensity becomes 50% of an initial brightness is defined as a light emission lifetime of the EL element, the result shows that the EL element to which the voltage is applied by the voltage application method 3 has a light emission lifetime about 20 times as long as the EL element to which the voltage is applied by the voltage application method 1. Since the light emission is generated only when the negative voltage is applied, it is considered that this difference in light emission lifetime is caused by a difference in temperature of the EL element. That is, the result shows that the voltage application method which suppresses the heat generation of the EL element leads to an increase in light emission lifetime.

The EL element fabricated in this experiment contains the germanium atoms or germanium oxides as the light emitter, but the EL element may contain ZnS as the light emitter. In addition, the EL element may contain both of the germanium atoms or germanium oxides and ZnS. The EL element can be fabricated by additionally introducing ZnS to the light emitting layer containing the germanium atoms or germanium oxides, by ion implantation or CVD.

### 2. Relationship Between Germanium Oxide and Light Emission

By a method shown hereinafter, it has been confirmed that the germanium oxides (including Ge⁴⁺ and Ge²⁺) are related to the light emission of the light emitting element according to the present invention.

First, two hypotheses about the light emitting mechanism were made. According to a first hypothesis, Ge nanoparticles cause the light emission due to a quantum size effect. This light emission mechanism is the same as a light emission mechanism of normal nanoparticles, and a light emission wavelength depends on a particle size. According to a second hypothesis, the germanium oxides (including Ge⁴⁺ and Ge²⁺) are related to the light emission. An energy level difference of GeO (Ge²⁺) between an excited state and a ground state is 2.9 to 3.2 eV (387 to 427 nm) (refer to L. Skuja, J. Non-Cryst. Solids, 239 (1998) 16-48.), so that according to the second hypothesis, the light emission wavelength is about 387 to 427 nm, and it is considered that this wavelength does not depend on a particle size.

In order to verify which hypothesis of them is correct, light emitting elements were fabricated under variously different temperature conditions and implantation conditions, and an EL wavelength when the voltage was applied to each of the light emitting elements by each of the above methods was measured. The EL wavelength was measured with “spectrofluorophotometer RF-5300PC made by Shimadzu Corporation). A method for manufacturing the light emitting element was the same as that described in the “1. Effect confirming experiment” except that the heat treatment temperature and the Ge implantation amount were appropriately changed.

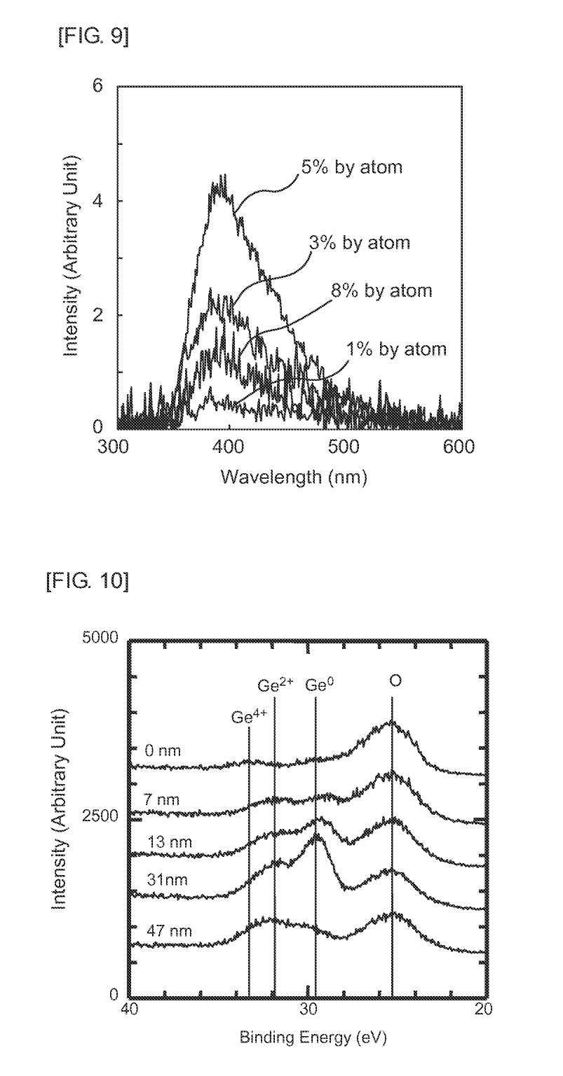

Obtained results are shown in FIG. 8 and FIG. 9. A temperature in FIG. 8 shows a heat treatment temperature (a time is one hour) after the Ge implantation. In addition, “% by atom” in FIG. 9 shows a Ge concentration in a silicon oxide film after the Ge implantation. A Ge concentration in FIG. 8 is 5.0% by atom, and a heat treatment temperature after the Ge implantation in FIG. 9 is 700° C. (a time is one hour).

Referring to FIG. 8 and FIG. 9, it is found that even when the heat treatment temperature or the Ge concentration is changed, a peak wavelength of EL is kept at roughly 390 nm. When the heat treatment temperature or the Ge concentration is changed, a size of the formed nanoparticle is also changed, so that when the light emission mechanism follows the first hypothesis, the peak wavelength of the EL should be shifted. Therefore, the wavelength of the EL confirmed in FIG. 8 and FIG. 9 cannot be explained by the first hypothesis. Meanwhile, the wavelength 390 nm falls within the range of the light emission wavelength (387 to 427) predicted in the second hypothesis.

As described above, it is found that the EL wavelength from the light emitting element in the present invention cannot be explained by the first hypothesis but can be explained by the second hypothesis. Therefore, it can be confirmed that the germanium oxides (including Ge⁴⁺ and Ge²⁺) are related to the light emission of the light emitting element of the present invention.

By the way, referring to FIG. 8, it is found that the heat treatment temperature is preferably 600 to 700° C. In addition, referring to FIG. 9, it is found that the Ge concentration is preferably 3.0% by atom or more, and more preferably 3.0 to 5.0% by atom.

### 3. Depth Direction Distribution of Ratios of Ge⁰, Ge²⁺, and Ge⁴⁺

A light emitting element was manufactured according to the method described in the “1. Effect confirming experiment”, and a depth direction distribution of the ratios of Ge⁰, Ge²⁺, and Ge⁴⁺ in the silicon oxide film was examined. A Ge concentration of the light emitting element manufactured here is 5.0% by atom, and a heat treatment temperature thereof is 800° C. (a time is one hour).

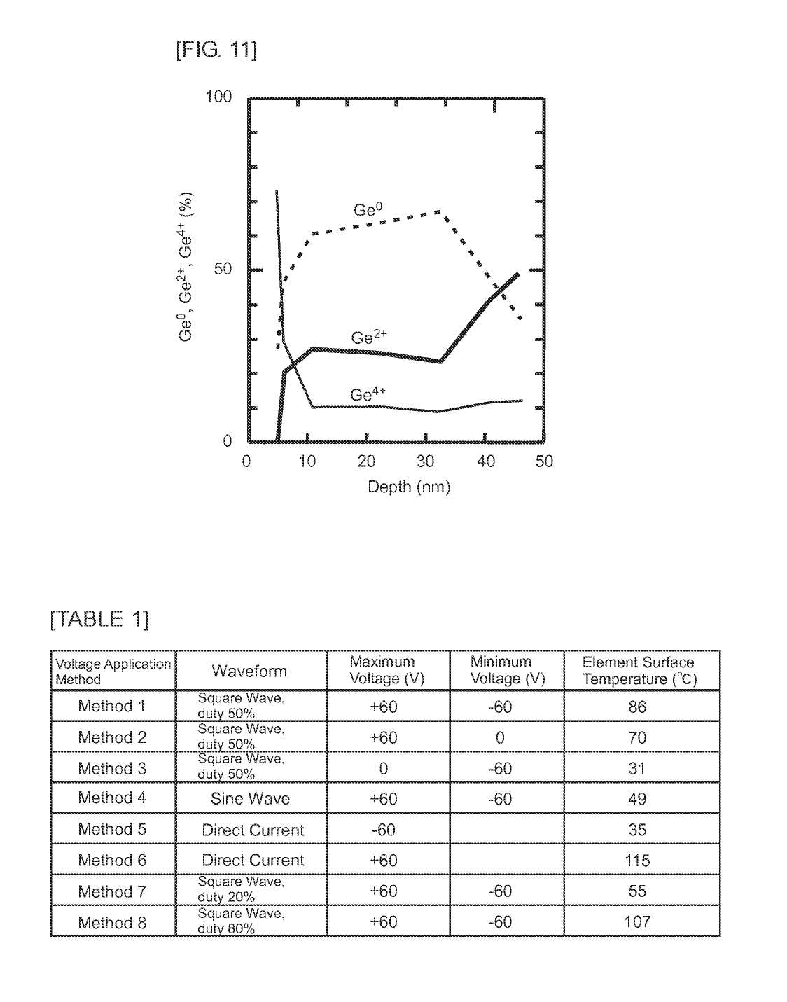

Since a range between a sample surface and a depth of several nm can be analyzed by the XPS in general, etching with argon ion beam and the XPS measurement were alternately performed to examine a change in ratio of Ge⁰, Ge²⁺, and Ge⁴⁺ in the depth direction in a region to a depth of 50 nm. An energy of the argon ion beam was 4 kV, a beam current was 15 mA, and irradiation was performed for 300 seconds at one time. FIG. 10 shows an XPS measurement result in this case such that graphs are moved in parallel in a vertical direction and aligned according to respective depths as can be easily understood. In addition, FIG. 11 shows a graph in which a state of the Ge atom contained in each depth is shown with the ratio of Ge⁰, Ge²⁺, and Ge⁴⁺.

According to this, in a region of depth 10 to 50 nm having relatively high Ge implantation concentration implanted by the implantation method described in the “1. Effect confirming experiment”, a ratio of Ge⁰ which is not oxidized is 30 to 70%. In addition, Ge⁴⁺ is between 0 and 20%, and about 10%. In addition, Ge²⁺ in which Ge is not completely oxidized but partially oxidized is between 10 and 50%.

The ratio of Ge⁰, Ge²⁺, and Ge⁴⁺ in each depth was determined by measuring the peak surface area S_{Ge} attributed to Ge⁰, the peak surface area S_{Ge2+} attributed to Ge²⁺, and the peak surface area S_{Ge4+} attributed to Ge⁴⁺, and calculating S_{Ge}/(S_{Ge}+S_{Ge2+}+S_{Ge4+}), S_{Ge2+}/(S_{Ge}+S_{Ge2+}+S_{Ge4+}), and S_{Ge4+}/(S_{Ge}+S_{Ge2+}+S_{Ge4+}) in each depth, in the XPS spectrum near 3d peak of Ge of the spectrum. The XPS spectrum was measured with Al, K-α ray (1486.6 eV) made monochromatic used as an X-ray source.

### DESCRIPTION OF REFERENCE SIGNS

1: Semiconductor substrate (Semiconductor layer)
3: Dielectric layer
5: Light emitter
7: First electrode
10: Second electrode
12: Light emitting element
13: Power supply circuit
15: Drive power supply
16: Rectifying diode
20: Light emitting device

1. A light emitting device comprising:
a light emitting element including a semiconductor layer, a first electrode, a dielectric layer sandwiched between the semiconductor layer and the first electrode, and a light emitter; and
a power supply circuit for applying a voltage between the semiconductor layer and the first electrode, wherein
the light emitter is formed in at least one region of regions in the semiconductor layer, in the dielectric layer, between the semiconductor layer and the dielectric layer, and between the first electrode and the dielectric layer,
the light emitting element emits light in one of first and second cases, but does not substantially emit light in the other case, the first case using a current applied to the dielectric layer under a condition that the semiconductor layer serves as a positive electrode and the first electrode serves as a negative electrode, the second case using a current applied to the dielectric layer under a condition that the semiconductor layer serves as the negative electrode and the first electrode serves as the positive electrode, and
the power supply circuit is electrically connected to each of the semiconductor layer and the first electrode so that a unidirectional current flows in the dielectric layer while the light emitting element emits the light.

2. The device according to claim 1, wherein the light emitting element is higher in electric resistance in a case where the current flows in the dielectric layer while the light emitting element emits the light than in a case where the current flows in the dielectric layer while the light emitting element does not substantially emit the light.

3. The device according to claim 1, wherein the power supply circuit comprises a rectifying diode to apply the current to the dielectric layer provided between the semiconductor layer and the first electrode, and
the power supply circuit is supplied with a power from an AC power supply.

4. The device according to claim 1, wherein the power supply circuit is supplied with a power from a DC power supply.

5. The device according to claim 1, wherein
the semiconductor layer is made of an n-type semiconductor or a p-type semiconductor, and
the power supply circuit is electrically connected to each of the semiconductor layer and the first electrode so that the semiconductor layer serves as the positive electrode and the first electrode serves as the negative electrode when the semiconductor layer is made of the n-type semiconductor, while the power supply circuit is electrically connected to each of the semiconductor layer and the first electrode so that the semiconductor layer serves as the negative electrode and the first electrode serves as the positive electrode when the semiconductor layer is made of the p-type semiconductor.

6. The device according to claim 1, wherein the semiconductor layer is made of the n-type semiconductor having an impurity concentration of 5×10¹⁵ cm⁻³ or lower, or is made of the p-type semiconductor having an impurity concentration of 5×10¹⁵ cm⁻³ or lower.

7. The device according to claim 1, wherein the light emitter comprises germanium atoms.

8. The device according to claim 1, wherein the light emitter comprises ZnS.

9. The device according to claim 1, wherein the light emitting element has a surface temperature of 60° C. or lower in the case where the current flows in the dielectric layer while the light emitting element emits the light.
